(19) United States
(12) Patent Application Publication
(10) Pub. No.: US 2011/0227658 A1
(43) Pub. Date: Sep. 22, 2011

(54) RESONATOR ELEMENT, PIEZOELECTRIC DEVICE, AND ELECTRONIC DEVICE

(75) Inventor: Hideo TANAYA, Suwa (JP)

(73) Assignee: SEIKO EPSON CORPORATION, Tokyo (JP)

(21) Appl. No.: 13/044,106

(22) Filed: Mar. 9, 2011

(30) Foreign Application Priority Data
Mar. 16, 2010 (JP) 2010-058808
Dec. 8, 2010 (JP) 2010-273256

(51) Int. Cl. H03B 28/00

(52) U.S. Cl. 331/156

(57) ABSTRACT

A resonator element which can achieve a reduction in size while maintaining vibration characteristics, and a piezoelectric device and an electronic device, are to be provided. A quartz crystal resonator element has a base portion, a pair of arm portions extending from the base portion as a root, and a cut-out portion formed by reducing the width of the base portion in the width direction from each side of the arm portions. The root has a first root portion positioned on a side where the arm portions are opposed to each other, and a second root portion positioned on a side where the arm portions are not opposed to each other, and a relationship between a length A from the first root portion to the second root portion and a length B from the first root portion to an inner end portion of the cut-out portion is A≧B.

### BACKGROUND

1. Technical Field

The present invention relates to a resonator element having a resonating arm, and a piezoelectric device and an electronic device having the resonator element.

2. Related Art

Typically, a resonator element in which flexural vibration occurs has a base portion, a resonating arm that extends from the base portion and is formed along the width direction, a long groove and an electrode provided in the resonating arm, and a cut-out portion formed to reduce the width of the base portion in the width direction. In this case, the resonating arm is set so that the width of the resonating arm is gradually reduced from the base portion side to the tip end side and the width of the resonating arm is constant or gradually increased on a side closer to the tip end than a width change point. In addition, the long groove and the electrode are formed between the base portion side and the width change point of the resonating arm. In the resonator element having the above configuration, since the cut-out portion is provided, it is possible to suppress a phenomenon that occurs when the resonating arm vibrates in unnecessary directions, a so-called leakage of vibration from propagating to the base portion from the resonating arm. Moreover, due to the reduction in the width of the resonating arm and the increase in mass of the tip end side of the resonating arm, it is possible to reduce the length of the resonating arm without an increase in the frequency of the resonating arm. Therefore, it is possible to reduce the size of the resonator element while maintaining vibration characteristics (for example, JP-A-2006-311090).

However, although this technique enables the reduction in the size of the resonator element according to the related art by providing the cut-out portion and the width change point and reducing the width of the resonating arm, recently, there has been a demand for a further reduction in the size of the resonator element. Therefore, when an attempt is made to reduce the size of the resonator element in relation to this, there is a problem in that there may be a case where it is difficult to reliably maintain the vibration characteristics simply by providing only the cut-out portion and the width change point.

### SUMMARY

An advantage of some aspects of the invention is to solve at least a part of the above-described problem, and the invention can be implemented as the following embodiments or application examples.

### APPLICATION EXAMPLE 1

According to this application example of the invention, there is provided a resonator element including: a base portion; a pair of arm portions which extend from the base portion as a root and are arranged along a width direction of the base portion; a groove provided in the arm portion; a supporting portion which supports the base portion; a connection portion which connects the base portion to the supporting portion; and a cut-out portion which is formed by reducing a width of the base portion in the width direction from a side of each of the arm portions, wherein the root has a first root portion positioned on a side where the arm portions are opposed to each other, and a second root portion positioned on a side where the arm portions are not opposed to each other, and a relationship between a length A from the first root portion to the second root portion and a length B from the first root portion to an inner end portion of the cut-out portion is A≧B.

In the resonator element, each of the arm portions is formed integrally with the base portion and arranged along the width direction of the base portion. In addition, the width of the arm portion at the root which is the contact point with the base portion is the length A between the first root portion and the second root portion. In this case, the first and second root portions are positioned along the width direction of the base portion, and moreover, the first root portion of each of the arm portions is disposed on the side where the arm portions are opposed to each other, that is, the arm portions face each other. In addition, the base portion is provided with the cut-out portion, the cut-out portion is formed by cutting out the base portion in the width direction from the end portion of the base portion from which the arm portions are provided, and the end of the inner side of the base portion is an inner end portion. The arm portions and the cut-out portions are provided in the base portion so as to form pairs, and the shortest distance between the first root portion of the arm portion and the inner end portion of the cut-out portion is the length B. In the resonator element having the above configuration, the relationship between the length A from the first root portion of the arm portion to the second root portion and the length B from the first root portion to the inner end portion with which the first root portion form the pair is set to A≧B. When the length A and the length B have the relationship of A≧B, the arm portion vibrates about, as an axis, a portion corresponding to the length B between the first root portion and the inner end portion which is shorter than the length A. That is, stress due to the vibration of the arm portion is concentrated on the cut-out portion, and thus propagation of a so-called leakage of vibration to the base portion can be suppressed, so that it is possible for the resonator element to vibrate stably even though the size thereof is reduced. On the other hand, when the length A and the length B have a relationship of A≦B, the arm portion vibrates about, as an axis, a portion corresponding to the length A between the first root portion and the second root portion which is shorter than the length B, and thus the effect of providing the cut-out portion is reduced, so that it becomes difficult to suppress the propagation of the leakage of vibration to the base portion. Accordingly, the resonator element in which the relationship between the length A from the first root portion to the second root portion and the length B from the first root portion to the inner end portion of the cut-out portion is set to A≧B can achieve a reduction in size while maintaining vibration characteristics.

### APPLICATION EXAMPLE 2

In the resonator element according to the above application example, it is preferable that a width of the arm portion be gradually reduced from a side of the base portion toward a side of a tip end thereof.

In this configuration, the arm portion has, as the maximum width, the length A of the root portion which is the contact point with the base portion, and the width of the arm portion is gradually reduced as being extending from the base portion toward the tip end and thus is gradually thinned. That is, in the arm portion having this shape, the root has highest rigidity. Accordingly, even though the width of the arm is further reduced for the purpose of a reduction in the size of the resonator element, it is possible to stably support the vibration of the arm portion.

### APPLICATION EXAMPLE 3

It is preferable that the resonator element according to the above application example further include a hammerhead provided at the tip end of the arm portion, the hammerhead have a width greater than that of the tip end of the arm portion, and a relationship between the width C of the hammerhead and a length A of the root of the arm portion be A≧C.

In this configuration, the arm portion has the hammerhead, and since the tip end of the arm portion including the hammerhead is increased in mass, mass balance is changed from that of a case where only the arm portion is provided. Accordingly, the arm portion can be easily allowed to vibrate at a predetermined frequency by adjusting the balance between the length of the arm portion and the mass of the hammerhead. For example, when the length of the arm portion is reduced, the arm portion flexes at a high frequency. Therefore, when the hammerhead is provided at the tip end of the arm portion, adjustment such as suppression of the frequency can be achieved. Therefore, even though the length of the arm portion is reduced, an increase in frequency can be suppressed, so that it is possible for the arm portion to maintain the same vibration. However, when the width of the hammerhead is broadened, stress concentration of the root of the arm portion excessively occurs, so that the vibration of the arm portion becomes unstable. Therefore, by setting the relationship between the width C of the hammerhead and the length A of the root of the arm portion to A≧C, the rigidity of the root of the arm portion is ensured, so that it is possible to stabilize the vibration of the arm portion.

### APPLICATION EXAMPLE 4

In the resonator element according to the above application example, it is preferable that a head tapered portion be formed at a position where the arm portion and the hammerhead are connected to each other.

In this configuration, excessive fluctuation of width over the hammerhead from the arm portion is eliminated, and concentration of stress on the connection position can be avoided. That is, the arm portion and the hammerhead are smoothly connected at the connection position in the head tapered portion so that there is no point having significantly degraded rigidity. Therefore, the arm portion and the hammerhead are integrated and reliably flex, so that it is possible for the resonator element to stably vibrate.

### APPLICATION EXAMPLE 5

According to this application example of the invention, there is provided a piezoelectric device at least including the resonator element according to the above application example.

### APPLICATION EXAMPLE 6

According to this application example of the invention, there is provided a piezoelectric device including: the resonator element according to the above application example; and a circuit portion electrically connected to the resonator element.

The piezoelectric device has the resonator element, and the root of the arm portion included in the resonator element is set so that the relationship between the length A from the first root portion to the second root portion and the length B from the first root portion to the inner end portion of the cut-out portion is A≧B. Accordingly, stress due to the vibration of the arm portion is concentrated on the cut-out portion, and thus propagation of a so-called leakage of the vibration to the base portion can be suppressed, so that it is possible for the resonator element to ensure stable vibration even through the size of the resonator element is reduced. The piezoelectric device configured by packaging the resonator element can achieve a reduction in size while maintaining vibration characteristics. In addition, the piezoelectric device may further include, in addition to the resonator element circuit portions electrically connected to the resonator element.

### APPLICATION EXAMPLE 7

According to this application example of the invention, there is provided an electronic device including: the resonator element according to the above application example; and a circuit portion electrically connected to the resonator element.

In the electronic device, since the resonator element which has a small size and stable vibration characteristics as described above is included, it is possible for the electronic device to maintain stable functions as an electronic device.

### BRIEF DESCRIPTION OF THE DRAWINGS

The invention will be described with reference to the accompanying drawings, wherein like numbers reference like elements.

FIG. 1 is a plan view illustrating the outer appearance of a quartz crystal resonator element.

FIG. 2 is a plan view illustrating the detailed shape of a resonating arm.

FIG. 3 is a schematic diagram illustrating the configurations of excitation electrodes of the resonating arm.

FIG. 4 is a graph showing a relationship between the settings of a cut-out portion and the CI value.

FIG. 5A is a plan view illustrating a piezoelectric device, and FIG. 5B is a cross-sectional view illustrating the piezoelectric device.

FIG. 6 is a flowchart showing a manufacturing process of the piezoelectric device.

FIG. 7 is a perspective view illustrating a simplified configuration of a portable phone as an example of an electronic device.

FIG. 8 is a circuit block diagram of the portable phone.

FIG. 9 is a perspective view illustrating a simplified configuration of a personal computer as an example of the electronic device.

### DESCRIPTION OF EXEMPLARY EMBODIMENTS

Hereinafter, a piezoelectric resonator element and a piezoelectric device according to the invention will be described with reference to the accompanying drawings. In embodiments, as a resonator element, a quartz crystal resonator element having tuning fork-type resonating arms is exemplified, and the resonator element includes a resonating arm having an arm portion and a hammerhead provided at the tip end of the arm portion, a cut-out portion provided in a base portion from which the arm portion extends, and the like.

### Embodiment

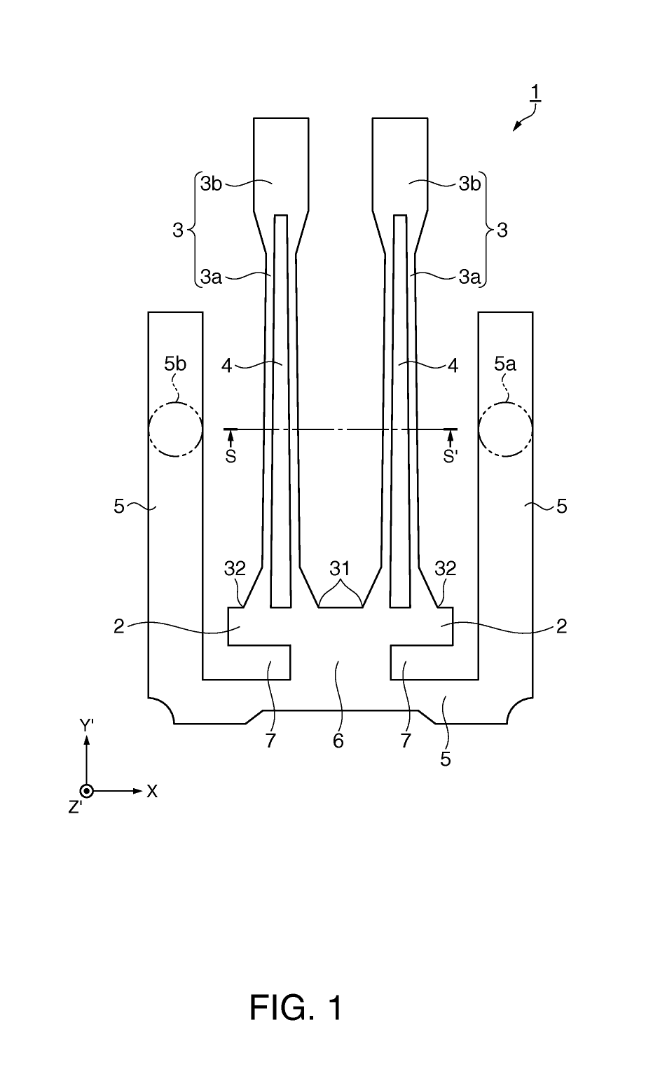

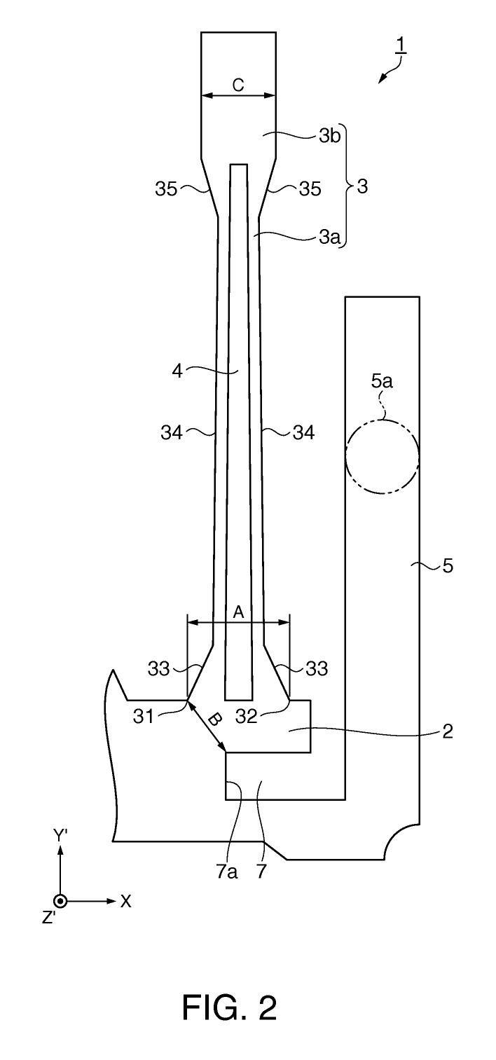

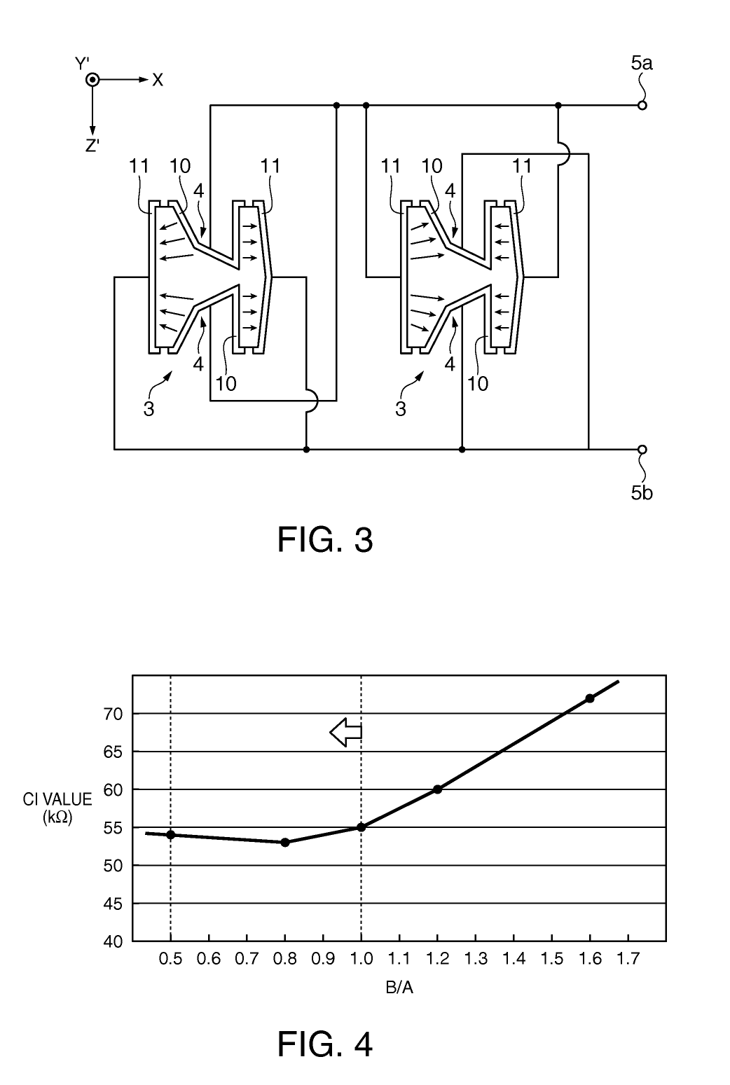

FIG. 1 is a plan view illustrating the outer appearance of a quartz crystal resonator element. In addition, FIG. 2 is a plan view illustrating the detailed shape of a resonating arm, where only one of a pair of resonating arms 3 which form a tuning fork is illustrated. First, as illustrated in FIG. 1, the quartz crystal resonator element (resonator element) 1 has a base portion 2 having the X axis direction as the width direction, two resonating arms 3 extending, that is, protruding from the base portion 2 in the Y′ axis direction, and a groove 4 which is provided in each of the resonating arms 3 into a substantially rectangular shape in a plan view. In addition, on the surfaces of the resonating arms 3 and the grooves 4, excitation electrodes (not shown) are formed, and by applying a driving current to the excitation electrodes, the resonating arms 3 flexes and vibrates in the width direction. The excitation electrodes will be described with reference to FIG. 3. In addition, the quartz crystal resonator element 1 has a supporting portion 5 formed in the U shape bending at a position of the opposite side of the base portion 2 to the side thereof from which the resonating arms 3 toward the direction along the resonating arms 3 and extending, a connection portion 6 for connecting the base portion 2 to the supporting portion 5 and a pair of cut-out portions 7 formed by cutting out the base portion 2 from which the resonating arms 3 extend from each end side thereof along the X axis to reduce the width of the base portion 2 in the width direction. In this case, the cut-out portions 7 formed by reducing the width of the base portion 2 exits between the base portion 2 and the supporting portion 5.

Moreover, each of the resonating arms 3 has an arm portion 3a extending from the base portion 2 and a hammerhead 3b provided at the tip end of the extending arm portion 3a. In the root which is a contact point between the arm portion 3a and the base portion 2, a first root portion 31 is positioned on the side opposed to the resonating arm 3, and a second root portion 32 is positioned on the side that is not opposed to the arm portion 3a, that is, at the end portions of the base portion 2. The first and second root portions 31 and 32 are provided along the width direction of the base portion 2 so as to connect and support the arm portion 3a and the hammerhead 3b to the base portion 2. In addition, the supporting portion 5 has mount portions 5a and 5b for fixing the quartz crystal resonator element 1 to a package or the like, and the mount portions 5a and 5b are respectively provided on the both sides of the supporting portion 5 having the U shape along the resonating arms 3.

Here, a quartz crystal from which the quartz crystal resonator element 1 is formed will be described simply. The quartz crystal resonator element 1 is cut from a quartz crystal column which is a hexagonal column, and the quartz crystal column has the Z axis which is the optical axis in the longitudinal direction of the column, the X axis which is the electrical axis parallel to the edges of the hexagon on the X-Y plane that is a hexagonal plane perpendicular to the Z axis, and the Y axis which is the mechanical axis perpendicular to the X axis. In addition, the X axis parallel to the edges of the hexagon has properties of a trigonal quartz crystal in that three faces formed on the X-Y plane by the X axis at three equal angles of 120° have the same properties in the etching rate in the etching direction and the like. In the quartz crystal column, the quartz crystal resonator element 1 is cut from a quartz crystal Z plate which extends along the X-Y plane and is tilted at an angle of 5° around the X axis as seen from the intersection (the origin of coordinates) of the X and Y axes. As illustrated in FIG. 1, the width direction of the base portion 2 is the X axis, the longitudinal direction of the resonating arm 3 is the Y′ axis direction, and the thickness direction of the quartz crystal resonator element 1 is the Z′ axis direction.

Next, the detailed shapes of the resonating arm 3 and the cut-out portion 7 and the like will be described with reference to FIG. 2. The resonating arm. 3 illustrated in FIG. 2 is only one of the pair of resonating arms 3. The resonating arm 3 extends from the first and second root portions 31 and 32 which are the root of the arm portion 3a connected to the base portion 2 in the X direction which is the width direction of the resonating arm 3, and the width of the resonating arm 3 from the first root portion 31 to the second root portion 32 is a length A. The arm portion 3a has a width gradually reduced from the root having the length A to the tip end, so that the width thereof is reduced in the width direction. In addition, the reduction in the width of the arm portion 3a has two stages: the first stage is a first tapered portion 33 extending toward the tip end while the width is reduced from the root having the length A, and the second stage is a second tapered portion 34 which is connected from the first tapered portion 33 and of which the width is reduced in a different manner from the first tapered portion 33. The first tapered portion 33 has a greater width reduction ratio than that of the second tapered portion 34; that is, the slope thereof is set to be greater than that of the second tapered portion 34. Moreover, the length of the first tapered portion 33 extending toward the tip end is set to be significantly shorter than that of the second tapered portion 34, so that most of the length of the arm portion 3a is the second tapered portion 34.

In addition, the cut-out portion 7 provided in the base portion 2 is formed by cutting out the base portion 2 from the end portion toward the inner portion, and the flat end face of the dead end of the inner portion of the base portion 2 is an inner end portion 7a. By the position of the inner end portion 7a, the cut-out length of the cut-out portion 7 in the base portion 2 is set. The position of the inner end portion 7a in the cut-out portion 7 is set so that the shortest length B from the first root portion 31 to the inner end portion 7a is shorter than the width A from the first root portion 31 to the second root portion 32 and thus a relationship of A≧B is satisfied. In addition, the other resonating arm 3 and cut-out portion 7 have the configuration set in the same manner.

In the quartz crystal resonator element 1 having the above configuration, the width A from the first root portion 31 to the second root portion 32 at the contact point between the arm portion 3a and the base portion 2 is the maximum width of the arm portion 3a, and the root portion has the highest rigidity. Accordingly, the quartz crystal resonator element 1 stably supports the vibration of the arm portion 3a. In addition, in the quartz crystal resonator element 1, when the resonating arm 3 vibrates, the resonating arm 3 vibrates about, as an axis, a portion corresponding to the shorter one of the length A of the root and the shortest length B from the first root portion 31 to the inner end portion 7a. Therefore, in the quartz crystal resonator element 1 in which the length A and the length B are set to satisfy the relationship of A≧B, the resonating arm 3 vibrates about, as an axis, a portion corresponding to the length B between the first root portion 31 and the inner end portion 7a which has a shorter length. Accordingly, stress that occurs as the resonating arm 3 vibrates is concentrated on the cut-out portion 7, and thus it is possible to suppress a leakage of the vibration from propagating to the base portion 2. Therefore, the resonating arm 3 excludes the loss due to the leakage of the vibration, so that stable vibration can be maintained and a reduction in size can be achieved.

Accordingly, when the length A and the length B have a relationship of A≦B, the resonating arm 3 vibrates in the width direction (X axis direction) about, as an axis, a portion corresponding to the length A between the first and second root portions 31 and 32 which has a shorter length. In this case, it is found that vibration in a direction other than the width direction, for example, in the Z′ axis direction increases as the size of the resonating arm 3 is reduced, so that the effect of suppressing vibration by cutting-out is reduced, and the CI (Quartz crystal Impedance) is increased, resulting in vibrations with great losses of vibration energy. That is, in the case of the relationship of A≦B, the effect of suppressing the leakage of the vibration by providing the cut-out portion 7 is also reduced as a result, so that it becomes difficult to suppress the propagation of the leakage of the vibration toward the base portion 2 as compared with the case where the resonating arm 3 vibrates about a portion corresponding to the length B as an axis. Accordingly, the quartz crystal resonator element 1 in which the cut-out portion 7 is included and (the length A from the first root portion 31 to the second root portion 32)≧(the length B from the first root portion 31 to the inner end portion 7a of the cut-out portion 7) is set, a further reduction in size is possible while maintaining vibration characteristics, and vibration stably occurs even with the reduction in size.

In addition, the resonating arm 3 of the quartz crystal resonator element 1 has the hammerhead 3b at the tip end of the arm portion 3a, the hammerhead 3b has a larger width than that of the tip end of the arm portion 3a, and the width is the length C. In addition, at a position where the hammerhead 3b and the arm portion 3a are connected to each other, a head tapered portion 35 is provided in order to remove excessive fluctuation of the width from the arm portion 3a to the hammerhead 3b. The head tapered portion 35 has an inverted taper shape unlike the first and second tapered portions 33 and 34, and the width of the head tapered portion 35 is gradually increased in a direction from the tip end of the arm portion 3a to the hammerhead 3b such that the arm portion 3a and the hammerhead 3b are smoothly connected to each other. In addition, the head tapered portion 35 belongs to the hammerhead 3b, and the width C of the hammerhead 3b is shorter than the width A from the first root portion 31 to the second root portion 32 to have a relationship of A≧C.

In the resonating arm 3 having the hammerhead 3b, the mass of the tip end of the arm portion 3a is increased. Therefore, even though the length extending from the base portion 2 is reduced for the purpose of the reduction in size, flexure at a high frequency can be suppressed, so that it is possible to maintain the same vibration regardless of, for example, the length of the resonating arm 3. That is, when the hammerhead 3b is provided in the arm portion 3a, desired vibration can be easily achieved by adjusting the frequency of the resonating arm 3. However, when the length C is increased by enlarging the width of the hammerhead 3b, stress of vibration is concentrated on the root of the arm portion 3a, so that the root may be damaged and vibration of the resonating arm 3 becomes unstable. Therefore, by setting (the length A from the first root portion 31 to the second root portion 32)≧(the width C of the hammerhead 3b), rigidity of the root of the resonating arm 3 can be ensured, thereby stabilizing the vibration of the resonating arm 3. Moreover, as the head tapered portion 35 is included in the resonating arm 3, the width between the arm portion 3a and the hammerhead 3b is not excessively changed, and the arm portion 3a and the hammerhead 3b are smoothly connected to each other. That is, the resonating arm 3 has a configuration in which even at a position where the arm portion 3a and the hammerhead 3b which have different widths are connected, there is no point having significantly degraded rigidity, and stress is less likely to be concentrated. Accordingly, the resonating arm 3 flexes as the arm portion 3a and the hammerhead 3b form one body and thus vibrates more stably.

Continuously, the groove 4 provided in the resonating arm 3 will be described with reference to FIG. 2 and the schematic diagram illustrating the configurations of the excitation electrodes provided in the resonating arm illustrated in FIG. 3. FIG. 3 shows a cross-section taken along the line S-S′ of FIG. 1. The grooves 4 are provided in both front and rear surfaces that define the thickness of each of the resonating arms 3 in the Z′ axis direction, and extend along the longitudinal direction (Y′ axis direction) at the center position of the width of the resonating arm 3. The length of the extending groove 4 has a starting point which is the root of the resonating arm 3 and an end point which is at an inner position of the hammerhead 3b over the position where the arm portion 3a and the hammerhead 3b are connected. In addition, the groove 4 extends along the second tapered portion 34 of the arm portion 3a with a width of 70% to 98% of the width of the arm portion 3a as it is to reach the hammerhead 3b. In addition, the groove 4 in the first tapered portion 33 of the arm portion 3a does not extend along the first tapered portion 33, and reaches the root with the same width as that at the contact point between the first and second tapered portions 33 and 34. Moreover, the depth of the groove 4 is 40% to 48% of the thickness of the resonating arm 3, and has a substantially trapezoidal shape in the X-Z′ cross-section (FIG. 3).

In addition, the resonating arm 3 having the groove 4 is provided with the excitation electrodes as illustrated in FIG. 3. The excitation electrodes include a groove excitation electrode 10 provided in the groove 4 and an arm excitation electrode 11 provided on the surface of the arm portion 3a where the groove 4 is not formed, that is, two excitation electrodes. The groove excitation electrode 10 and the arm excitation electrode 11 are provided between the root of the resonating arm 3 and the front position of the head tapered portion 35. In addition, the groove excitation electrode 10 and the arm excitation electrode 11 are connected to the mount portion 5a or 5b via wiring formed on the base portion 2, the connection portion 6, and the supporting portion 5. In addition, the excitation electrodes and wiring are not shown in FIG. 2.

Next, the flexure of the resonating arm 3 that occurs as a driving voltage is applied to the excitation electrodes will be described. As illustrated in FIG. 3, the groove excitation electrode 10 of the one resonating arm 3 and the arm excitation electrode 11 of the other resonating arm 3 are connected to the same mount portion 5a, and the arm excitation electrode 11 of the one resonating arm 3 and the groove excitation electrode 10 of the other resonating arm 3 are connected to the same mount portion 5b. In this case, an alternating current is applied to the mount portions 5a and 5b, and an alternating voltage is applied as a driving voltage. That is, when the driving voltage is applied to each of the groove excitation electrode 10 and the arm excitation electrode 11 of the resonating arm 3, an electric field having direction as indicated by the arrows is generated inside the resonating arm 3. With regard to the electric field illustrated in FIG. 3, the mount portion 5a has a positive (+) potential, and the mount portion 5b has a negative (−) potential. Accordingly, one side of the arm excitation electrode 11 of the resonating arm 3 elongates in the Y′ axis direction, and the other side thereof shrinks in the Y′ axis direction, so that the resonating arms 3 flexes in a direction in which they become distant from each other or approach each other. In addition, when the potentials applied to the mount portions 5a and 5b are switched by the alternating voltage, the resonating arms 3 flex from the state where they become distant to each other to the state where they approach each other, or from the state where they approach each other to the state where they become distant from each other. As such, as the alternating voltage is applied to the mount portions 5a and 5b, the resonating arms 3 keep vibrating. In addition, with regard to the generation of the electric field, the resonating arm 3 is configured to strengthen the generated electric field. Specifically, since the resonating arm 3 has the groove 4, the electrode area is increased by providing the groove 4 in the groove excitation electrode 10. By increasing the electrode area, an increase in the electric field strength is achieved, so that the resonating arms 3 can flex more reliably.

Next, the basis of the relationship of (the length A from the first root portion 31 to the second root portion 32)≧(the length B from the first root portion 31 to the inner end portion 7a of the cut-out portion 7) which is a feature of the quartz crystal resonator element 1 will be described. FIG. 4 is a graph showing a relationship between the settings of the cut-out portion and the CI value. In the graph of FIG. 4, in a case where B/A is 1 or equal to or smaller than 1, the CI value is 55 kΩ when B/A is 1, the CI value is 53 kΩ when B/A is 0.8, and the CI value is 54 kΩ when B/A is 0.5. It can be derived that the CI value is low and stable. That is, the loss of vibration energy is small. Here, the case where B/A is 1 or equal to or smaller than 1 corresponds to A≧B. On the contrary, in a case where B/A is equal to or greater than 1, the CI value is 60 kΩ when B/A is 1.2, and the CI value is 72 kΩ when B/A is 1.6. It can be seen that the CI value is high and the loss of vibration energy due to the leakage of vibration or the like is increased. As a result shown by the graph, in the configuration in which the quartz crystal resonator element 1 satisfies the relationship of (the length A from the first root portion 31 to the second root portion 32)≧(the length B from the first root portion 31 to the inner end portion 7a of the cut-out portion 7), the quartz crystal resonator element 1 can maintain vibration excluding the loss of vibration and thus can achieve a reduction in size. In addition, in a case where B/A is equal to or smaller than 0.5, the length B which is from the first root portion 31 to the inner end portion 7a of the cut-out portion 17 is a half or less of the length A from the first root portion 31 to the second root portion 32, so that the quartz crystal resonator element 1 is vulnerable to impacts. Therefore, in the case where the quartz crystal resonator element 1 in the settings is used, it is preferable that whether or not the quartz crystal resonator element 1 is used in an environment with small impacts be considered.

In addition, for reference, the dimensions of the quartz crystal resonator element 1 which obtains the relationship of FIG. 4 are described. The thickness (Z′ axis direction) of the quartz crystal resonator element 1 is about 100 μm, the total length (Y′ axis direction) thereof is about 1,500 μm, and the total width (X axis direction) thereof is about 500 μm. In addition, the total length of the resonating arm 3 is about 1,300 μm, and in the details thereof, the arm portion 3a is about 800 μm in length and the total length of the hammerhead 3b including the connection position is about 500 μm. In addition, the length in the Y′ axis direction including the base portion 2, the connection portion 6, and the supporting portion 5 connected to the connection portion 6 is about 200 μm, and the cut-out portion 7 is provided by a length of 30% or more of the total length of the quartz crystal resonator element 1 according to the related art, so that it is possible to reduce the length to about 13%. Moreover, the groove 4 of the arm portion 3a has a length (Z′ axis direction) of 40 μm to 48 μm, and a width (X axis direction) of 70% to 98% of the width of the arm portion 3a along the second tapered portion 34. In addition, the length A from the first root portion 31 to the second root portion 32 ranges from 100 μm to 180 μm, the length B from the first root portion 31 to the inner end portion 7a of the cut-out portion 7 ranges from 100 μm to 180 μm, and the width C of the hammerhead 3b ranges from 100 μm to 180 μm. Even through the size of the quartz crystal resonator element 1 is reduced according to this example, by managing the position of the inner end portion 7a of the cut-out portion 7, the propagation of the leakage of vibration to the base portion 2 can be suppressed, and vibration characteristics can be maintained.

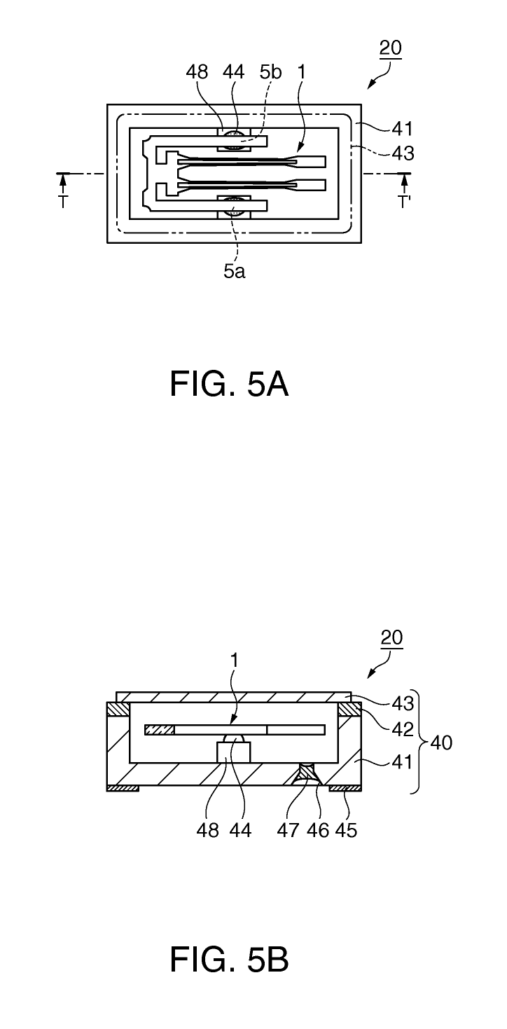

Next, a piezoelectric device having the quartz crystal resonator element 1 described above will be described. FIG. 5A is a plan view illustrating a piezoelectric device. In addition, FIG. 5B is a cross-sectional view illustrating the piezoelectric device and shows a cross-section taken along the line T-T′ of FIG. 5A. As illustrated in FIGS. 5A and 5B, the piezoelectric device 20 includes the quartz crystal resonator element 1 and a package 40 for accommodating the quartz crystal resonator element 1. The package 40 is constituted by a package base 41, a seam ring 42, a cover body 43, and the like.

The package base 41 is provided with a concave portion to accommodate the quartz crystal resonator element 1, and a connection pad 48 connected to the mount portions 5a and 5b of the quartz crystal resonator element 1 are provided in the concave portion. The connection pad 48 is connected to wiring inside the package base 41 so as to be electrically connected to an external connection terminal 45 provided in the outer peripheral portion of the package base 41. In addition, in the periphery of the concave portion of the package base 41, the seam ring 42 is provided, and moreover, in the bottom portion of the package base 41, a through-hole 46 is provided.

In addition, the quartz crystal resonator element 1 is adhered and fixed to the connection pad 48 of the package base 41 via a conductive adhesive 44. In addition, in the package 40 accommodating the quartz crystal resonator element 1, the concave portion of the package base 41 and the cover body 43 for covering the concave portion of the package base are welded to each other by the seam ring 42. The through-hole 46 of the package base 41 is filled with a sealing material 47 made of a metallic material or the like, and the sealing material 47 is fused and then solidified in a reduced-pressure atmosphere, so that the through-hole 46 is airtightly sealed to maintain the reduced-pressure state of the package base 41.

In the piezoelectric device 20 having the above configuration, the quartz crystal resonator element 1 is excited by a driving signal transmitted from the outside via the external connection terminal 45 and vibrates and oscillates at a predetermined frequency. The piezoelectric device 20 includes the quartz crystal resonator element 1 which can achieve a reduction in size while maintaining vibration characteristics by suppressing the propagation of the leakage of vibration to the base portion 2 and thus has stable vibration characteristics with a small size.

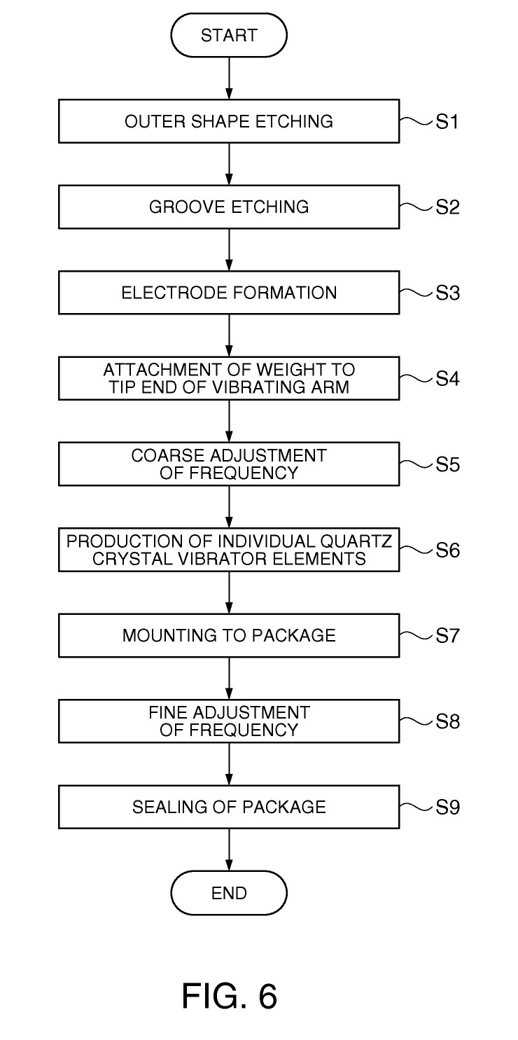

Next, a manufacturing process of the quartz crystal resonator element 1 and the piezoelectric device 20 will be described. FIG. 6 is a flowchart showing the manufacturing process of the piezoelectric device. In the manufacturing process, the quartz crystal resonator element 1 is manufactured using a wafer-shaped base material as a base, so that quartz crystal wafers are prepared as the wafer-shaped base materials. The quartz crystal wafer is formed by polishing the surface of the above-described quartz crystal Z plate into a flat plate shape.

In addition, in Step S1, outer shape etching is performed. First, a protective film such as a film formed by laminating a Cr film and an Au film is formed on the surface of the quartz crystal wafer, a resist film is applied on the surface of the protective film, and the resist film is patterned into the outer shape of the quartz crystal resonator element 1 by photolithography. Subsequently, the protective film is etched and removed by using the patterned resist film as a mask. After peeling off the resist film, a resist film is applied again and patterned into the outer shape and the groove shape. In this state, the exposed portions of the quartz crystal wafer are etched by hydrofluoric acid to form the outer shape of the quartz crystal resonator element 1. Accordingly, a number of outer-shape-completed products which are connected with thin connection portions and which will be the quartz crystal resonator elements 1 can be obtained from the quartz crystal wafer.

In Step S2, groove etching is performed. First, the protective film formed on the groove is etched. A quartz crystal face exposed by the etching corresponds to a plan shape of the groove 4 to be provided in the resonating arm 3. Subsequently, the exposed portions of the quartz crystal wafer are half-etched by hydrofluoric acid for a predetermined time, thereby forming the groove 4 in the resonating arm 3. In this case, the half-etching indicates a process of forming the depth of the groove 4 into 40% to 48% of the thickness of the resonating arm 3. After etching the groove 4, the resist film and the protective film are peeled off to proceed to Step S3.

In Step S3, electrode formation is performed. First, an electrode film made of a Cr film and an Au film in this case is formed on the entire surface of the quartz crystal wafer, and a resist film corresponding to the pattern of the groove excitation electrode 10 and the arm excitation electrode 11 is formed on the electrode film. Then the groove excitation electrode 10 and the arm excitation electrode 11 are formed by etching the electrode film. After etching the electrode, the resist film is peeled off to proceed to Step S4.

In Step S4, a weight is attached to the tip end of the resonating arm. This is performed by forming a metallic coating such as Au on the hammerhead 3b as a weight-attached film using sputtering or deposition. In addition, the weight-attached film is omitted in the foregoing description. The weight-attached film is formed to proceed to Step S5.

In Step S5, coarse adjustment of the frequency is performed. The coarse adjustment is performed by illuminating a part of the weight-attached film with a laser beam or the like to partially evaporate, thereby adjusting the mass of the hammerhead 3b. Accordingly, frequencies at which the resonating arms 3 vibrate can be adjusted to be substantially uniform. After the coarse adjustment, Step S6 is performed.

In Step S6, production of individual quartz crystal resonator elements is performed. That is, by breaking off the thin connection portions in the quartz crystal wafer, the quartz crystal resonator elements 1 in the connected state are divided into individual products. The description provided above is about the manufacturing process of the quartz crystal resonator element 1. After the production of individual quartz crystal resonator elements, in order to manufacture the piezoelectric device 20, Step S7 is performed.

In Step S7, the quartz crystal resonator element 1 is mounted in the package and fixed thereto. That is, the quartz crystal resonator element 1 is mounted in the package 40 as illustrated in FIG. 5A. After mounting the quartz crystal resonator element 1, Step S8 is performed.

In Step S8, fine adjustment of the frequency is performed. The fine adjustment is performed by applying a driving voltage to the quartz crystal resonator element 1, and illuminating the resonating arm 3 or the weight-attached film of the hammerhead 3b with an ion beam or a laser beam while monitoring the frequency, and adjusting the mass of the weight-attached film or the like. Accordingly, the resonating arm 3 of the quartz crystal resonator element 1 can be adjusted to accurately vibrate at a predetermined frequency. After the fine adjustment, Step S9 is performed.

In Step S9, the package is sealed. As illustrated in FIG. 5B, the cover body 43 is welded to the package base 41, the through-hole 46 is filled with the sealing material 47, and the quartz crystal resonator element 1 is sealed by the package 40. Accordingly, the piezoelectric device 20 having the quartz crystal resonator element 1 is completed.

In addition, the quartz crystal resonator element 1 and the piezoelectric device 20 are not limited to the embodiment described above, and modified examples described as follows may have the same effects as those of the embodiment.

### MODIFIED EXAMPLE 1

In the quartz crystal resonator element 1, the inner end portion 7a of the cut-out portion 7 is not limited to the flat end surface and may have an arc surface of a hemispheric shape. With the shapes, excessive concentration of stress on each part in the cut-out portion 7 can be avoided.

### MODIFIED EXAMPLE 2

The cut-out portion 7 is formed by cutting out the base portion 2 and thus is positioned between the base portion 2 and the supporting portion 5. However, the cut-out portion 7 may also be set to be formed at a position surrounded only by the base portion 2 while being distant from the supporting portion 5.

### MODIFIED EXAMPLE 3

The quartz crystal resonator element 1 is not limited to the quartz crystal for use, and other than the quartz crystal, a piezoelectric material such as lithium niobate (LINBO₃) or lead zirconate titanate (PZT) or a semiconductor such as silicon may also be used.

### MODIFIED EXAMPLE 4

The piezoelectric device 20 may have, in addition to the quartz crystal resonator element 1, a circuit portion electrically connected to the quartz crystal resonator element 1 in the package 40. Examples of the circuit portion include an oscillating circuit for oscillating the quartz crystal resonator element 1 and a detection circuit for detecting a physical quantity such as an angular velocity.

### MODIFIED EXAMPLE 5

The mount portions 5a and 5b of the supporting portion 5 are respectively provided on both sides. However, a configuration in which a plurality of mount portions is provided to support the quartz crystal resonator element 1 to the package 40 or the like more stably may also be employed.

### Electronic Device

In the quartz crystal resonator element according to each of the embodiments described above, stress due to vibration of the resonating arm is concentrated on the cut-out portion even though the size of the quartz crystal resonator element is reduced, so that the propagation of the leakage of vibration to the base portion is suppressed, thereby maintaining stable vibration. The quartz crystal resonator element can be applied to various electric devices, and the electronic devices obtained by providing the quartz crystal resonator element have high reliability. In addition, to the electronic device, resonators or oscillators described according to the embodiments may also be used.

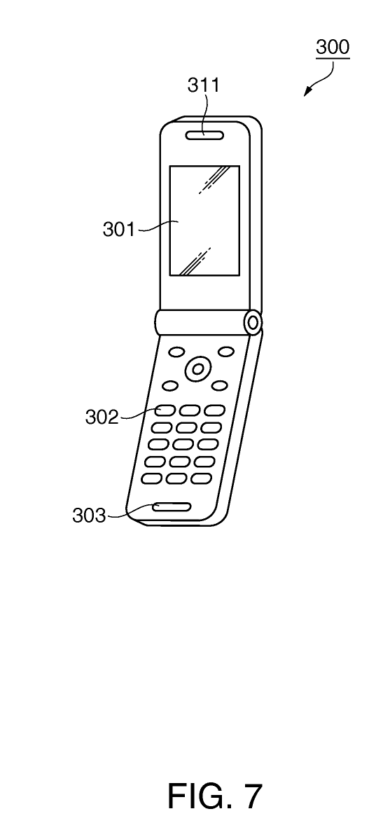

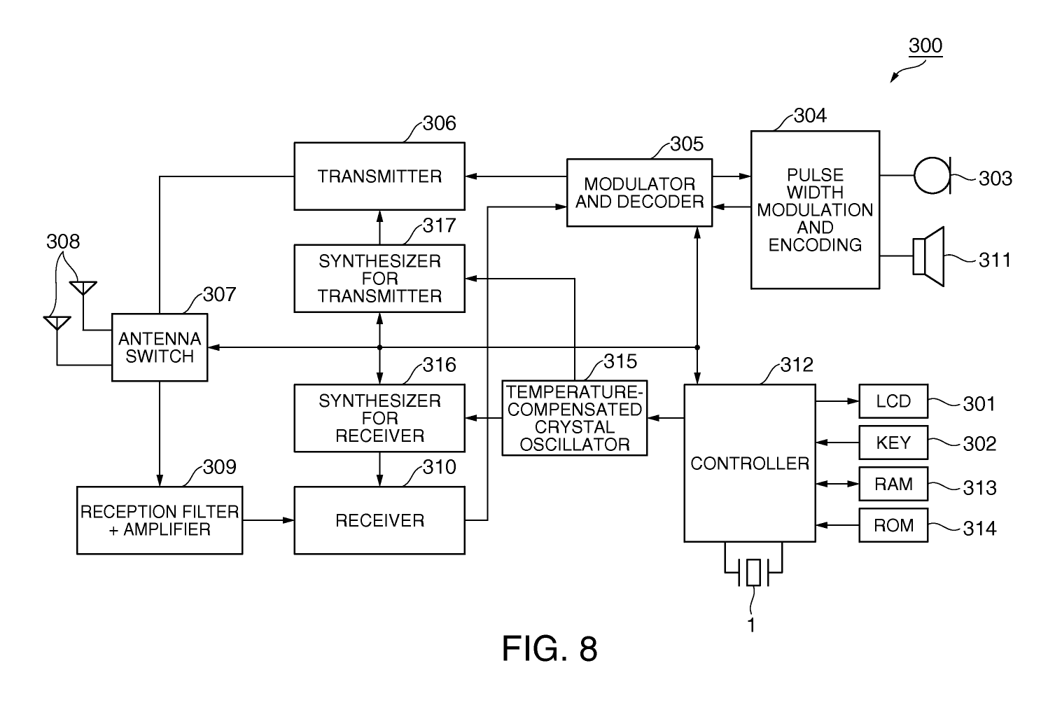

FIGS. 7 and 8 illustrate a portable phone as an example of the electronic device according to the invention. FIG. 7 is a perspective view illustrating a simplified configuration of the outer appearance of the portable phone, and FIG. 8 is a circuit block diagram for explaining circuits of the portable phone.

The portable phone 300 may use the quartz crystal resonator element 1 or the piezoelectric device 20 described above. In addition, in this example, the case of using the quartz crystal resonator element 1 is described. The configurations and operations of the quartz crystal resonator element 1 are denoted by like reference numerals, and description thereof will be omitted. In addition, when the quartz crystal resonator element 1 is used for the portable phone 300, a circuit portion which is electrically connected to the quartz crystal resonator element 1 and has function of driving at least the quartz crystal resonator element 1 is included, and description thereof is omitted.

As illustrated in FIG. 8, the portable phone 300 includes an LCD (liquid crystal display) 301 as a display unit, a key 302 as a unit for inputting numbers or the like, a microphone 303, a speaker 311, circuits (not shown), and the like.

As illustrated in FIG. 8, in a case where transmission is performed by the portable phone 300, as a user inputs his or her sound through the microphone 303, a signal is transmitted through a pulse width modulation and encoding block 304, a modulator and decoder block 305, a transmitter 306, an antenna switch 307 so as to be transmitted from an antenna 308.

A signal transmitted from a phone of other persons is received by the antenna 308 and is transmitted through the antenna switch 307, a reception filter 309, and a receiver 310 so as to be input to the modulator and decoder block 305. In addition, the modulated or decoded signal is transmitted through the pulse width modulation and encoding block 304 so as to be output through the speaker 311 as sound.

Here, a controller 312 for controlling the antenna switch 307, the modulator and decoder block 305, and the like is provided.

The controller 312 which operates with high precision is required in order to control the LCD 301 as the display unit and the key 302 as the unit for inputting numbers or the like, and furthermore, control a RAM 313, a ROM 314, and the like. In addition, there is a demand for a reduction in the size of the portable phone 300.

With this demand, the quartz crystal resonator element 1 described above is suitably used.

In addition, the portable phone 300 has a temperature-compensated crystal oscillator, a synthesizer 316 for receiver, a synthesizer 317 for transmitter, and the like as other component blocks, and description thereof is omitted.

In the quartz crystal resonator element 1 used for the portable phone 300, the relationship between the length A from the first root portion 31 to the second root portion 32 and the length B from the first root portion 31 to the inner end portion 7a of the cut-out portion 7 is set to A≧B, so that a further reduction in size thereof can be achieved while maintaining vibration characteristics. Therefore, the electronic component using the resonator element can maintain the function as an electronic device.

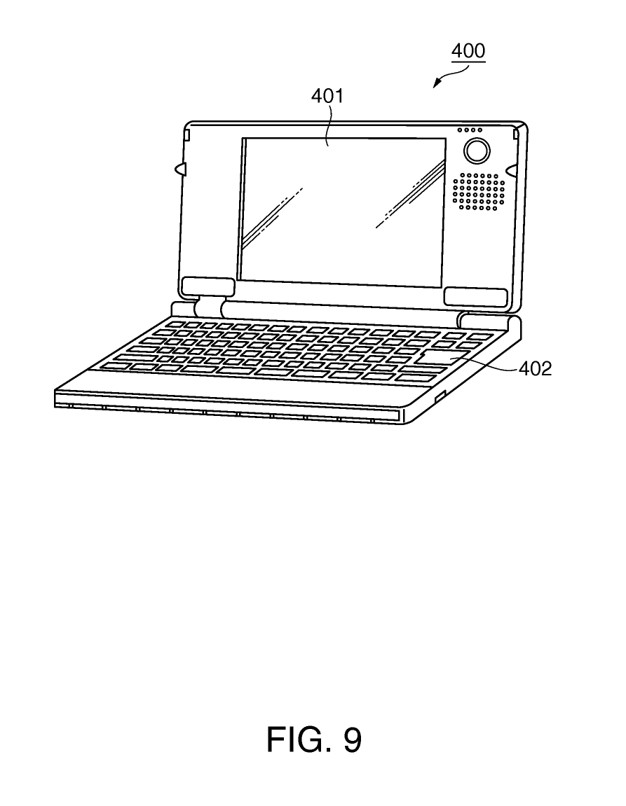

As an electronic device having the quartz crystal resonator element 1 according to the invention, a personal computer (mobile personal computer) 400 as illustrated in FIG. 9 may be employed. The personal computer 400 has a display unit 401, an input key unit 402, and the like and uses the quartz crystal resonator element 1 described above as a reference clock for electrical control.

In addition to the above-mentioned examples, examples of the electronic device having the quartz crystal resonator element 1 of the invention include a digital camera, an ink jet ejection apparatus (for example, an ink jet printer), a laptop personal computer, a television, a video camera, a video tape recorder, a car navigation apparatus, a pager, an electronic pocket book (including one with communication capability), an electronic dictionary, a calculator, an electronic game machine, a word processor, a work station, a television phone, a surveillance TV monitor, electronic binoculars, a POS terminal, a medical device (for example, an electronic thermometer, a sphygmomanometer, a glucose meter, an electrocardiogram measuring system, an ultrasonic diagnosis device, and an electronic endoscope), a fish finder, various measurement instruments, various indicators (for example, indicators used in vehicles, airplanes, and ships), a flight simulator, and the like.

While the electronic device of the invention has been described based on the embodiments, the invention is not limited to the embodiments, the configuration of the respective portions can be replaced with any configuration having the same function. Moreover, other arbitrary constituent elements may be added to the invention. Furthermore, arbitrary two or more configurations (features) among the respective embodiments may be combined with each other to implement the invention.

For example, although in the embodiments described above, a case where the quartz crystal resonator element has two resonating arms was described, the number of resonating arms may be three or more.

In addition, in the example of the above description, the resonator element 1 is used. However, instead of this, the piezoelectric device 20 may be used.

Moreover, the quartz crystal resonator element described in the embodiment may be applied to a gyro sensor or the like, in addition to a piezoelectric oscillator such as a voltage-controlled crystal oscillator (VCXO), a temperature-compensated crystal oscillator (TCXO), or an oven-controlled crystal oscillator (OCXO).

The entire disclosure of Japanese Patent Application Nos: 2010-058808, filed Mar. 16, 2010 and 2010-273256, filed Dec. 8, 2010 are expressly incorporated by reference herein.

1. A resonator element comprising:
a base portion;
a pair of arm portions which extend from the base portion as a root and are arranged along a width direction of the base portion;
a groove provided in the arm portion;
a supporting portion which supports the base portion;
a connection portion which connects the base portion to the supporting portion; and
a cut-out portion which is formed by reducing a width of the base portion in the width direction from a side of each of the arm portions,
wherein the root has a first root portion positioned on a side where the arm portions are opposed to each other, and a second root portion positioned on a side where the arm portions are not opposed to each other, and a relationship between a length A from the first root portion to the second root portion and a length B from the first root portion to an inner end portion of the cut-out portion is A≧B.

2. The resonator element according to claim 1, wherein a width of the arm portion is gradually reduced from a side of the base portion toward a side of a tip end thereof.

3. The resonator element according to claim 1, further comprising a hammerhead provided at the tip end of the arm portion,
wherein the hammerhead has a width greater than that of the tip end of the arm portion, and
a relationship between the width C of the hammerhead and a length A of the root of the arm portion is A≧C.

4. The resonator element according to claim 3, wherein a head tapered portion is formed at a position where the arm portion and the hammerhead are connected to each other.

5. A piezoelectric device comprising:
the resonator element according to claim 1.

6. A piezoelectric device comprising:
the resonator element according to claim 1; and
a circuit portion electrically connected to the resonator element.

7. An electronic device comprising:
the resonator element according to claim 1; and
a circuit portion electrically connected to the resonator element.
